(19) United States
(12) Patent Application Publication
(10) Pub. No.: US 2004/0053439 A1
(43) Pub. Date: Mar. 18, 2004

(54) Method for producing low-resistance ohmic contacts between substrates and wells in CMOS integrated circuits

(75) Inventors: Thomas Schafbauer, Wappinger Falls, NY (US); Klaus Schruefer, Munich (DE); Odin Prigge, Wappinger Falls, NY (US); Reinhard Mahnkopf, Wappinger Falls, NY (US); Walter Neumueller, Poughkeepsie, NY (US)

Correspondence Address: LERNER, DAVID, LITTENBERG,, KRUMHOLZ & MENTLIK, 600 SOUTH AVENUE WEST, WESTFIELD, NJ, 07090, US

(73) Assignee: Infineon Technologies North America Corp., San Jose, CA

(21) Appl. No.: 10/245,077

(22) Filed: Sep. 17, 2002

(51) Int. Cl. H01L 21/00; H01L 21/331

(52) U.S. Cl. 438/104; 438/348

(57) ABSTRACT

A method of fabricating a semiconductor connective region of a first conductivity type through a semiconductor layer of a second conductivity type which at least partly separates a bulk portion of semiconductor body (substrate) of the first conductivity type from a semiconductor well of the first conductivity type includes a step of implanting ions into a portion of the layer to convert the conductivity of the implanted portion to the first conductivity type. This electrically connects the well to the bulk portion of the body. Any biasing potential applied to the bulk portion of the body is thus applied to the well. This eliminates any need to form a contact in the well for biasing the well and thus allows the well to be reduced in size.

### FIELD OF THE INVENTION

This invention relates to a method for producing CMOS integrated circuits, and more particularly to a method for producing low-resistance ohmic contacts between p-type or n-type wells in such a circuit and a bulk portion of a semiconductor body (substrate) on which the circuit is manufactured.

### BACKGROUND OF THE INVENTION

The techniques for manufacturing Complementary Metal-Oxide-Semiconductor (CMOS) integrated circuits which consist of interconnected n-channel and p-channel Metal-Oxide-Semiconductor (MOS) transistors fabricated in a common semiconductor body (substrate) have been practiced for many years. In such a CMOS circuit, the n-channel transistors are fabricated in p-type conductivity regions of the semiconductor body known or referred to as p-wells, and the p-channel transistors are fabricated in n-type conductivity regions of the semiconductor body known or referred to as n-wells. In typical circuits the n- and p-wells are connected to voltage sources, or reference voltages, at known potentials. The known potentials are usually the two power supply potentials, but the wells may also be connected to other, known, potentials. These connections are usually implemented by forming on the surface of the wells of a first conductivity type, which is of the opposite conductivity type than the semiconductor body, a metallic, ohmic contact between the well and a metallic conductor which is connected to the source of the known potential. The wells of the second conductivity type are conductively connected to the bulk portion of the semiconductor body, which is of the same conductivity type as these wells, by allowing the bottom surfaces of these wells to be in contact with the bulk portion of the semiconductor body.

In the design and fabrication of CMOS integrated circuits it can be advantageous to place a heavily doped layer between the lower surface of the wells and the upper surface of the body. If the integrated circuit is a random access memory circuit, these layers can be used, for example, as a common electrode of a plurality of storage capacitors. For other types of circuits this layer can be used to connect all the wells of the first conductivity type to a common potential.

When such a layer is used it is no longer possible, unless special fabrication methods such as those described in this invention are taken, to allow the use of the bulk portion of the semiconductor body as the means for connecting wells to a reference voltage. If the bulk portion of the semiconductor body is not used as the means for connecting wells to a reference voltage, then a metallic contact to the well, or some other such means, must be used to contact the well.

In continuing efforts to produce such circuits which operate at higher speeds, which implement a higher degree of integration, and which can be manufactured at reduced cost, the size of the various features which constitute such an integrated circuit have been continually reduced. As the feature sizes are reduced, a metallic, ohmic contact to an n- or p-well can become a significant fraction of the size of such a well. This is particularly true if the well contains a single transistor.

Methods of reducing the amount of space in a CMOS integrated circuit which is dedicated to making ohmic contact to the wells have been the subject of continuing investigation and research. Wells of a first conductivity type can be conductively interconnected by making use of a buried conductor formed in combination with channel stops encircling each of the wells. Such a buried conductor lies near the surface of the semiconductor body, and is connected to a potential source at one or more points on the surface of the semiconductor body.

In the fabrication of the most recently disclosed types of CMOS circuits, used primarily in the fabrication of dynamic random access memory circuits (DRAM), a layer of the first conductivity type, is formed in the semiconductor body and lies between the wells of the second semiconductor type and the bulk portion of the semiconductor body, also of the second semiconductor type. The layer can be used, for example, as a common electrode of a plurality of storage capacitors. Unless special precautions are taken, this layer interrupts the ohmic connection between the wells of the second semiconductor type and the bulk portion of the semiconductor body.

One solution would be to leave openings in the layer where it is desired to allow the wells of the second conductivity type to contact the bulk portion of the semiconductor body. There are limitations to the application of this technique. Because of out-diffusion of the impurity atoms which dope the layer which takes place during the subsequent fabrication of the complete integrated circuit, the size of such an opening must be large enough so that the out-diffusion does not result in a closure of the opening. This method of connecting the wells to the bulk portion of the semiconductor body may lead to contact areas which are larger than desired, leading to a waste of area in the well.

Another solution is to make metallic or diffused contact to a portion of the top surface of the wells to facilitate biasing of the wells. This method of connecting the wells to a potential source leads to a waste of area in the well.

It is desirable to have a method of coupling a semiconductor well of a first conductivity type which is electrically isolated from a bias voltage applied to a semiconductor body of the first conductivity type by regions of opposite conductivity type, with a minimum opening through a portion of the region of the opposite conductivity type.

### SUMMARY OF THE INVENTION

The present invention is directed to an integrated circuit, e.g., a CMOS DRAM, and a process for fabricating an integrated circuit, e.g., a CMOS DRAM, which uses implantation of ions to form connective regions through an intervening layer of a first conductivity type to electrically connect a semiconductor well of an opposite second conductivity type to a bulk semiconductor region of the same second conductivity type.

Viewed from a first method aspect, the present invention is directed to a method of forming a first semiconductor connective region of a first conductivity type through a semiconductor layer of a second opposite conductivity type which at least partly separates a second semiconductor well region of the first conductivity type from a bulk portion of a semiconductor body of the first conductivity type. The method comprises the step of implanting ions of the first conductivity type into a portion of the semiconductor layer so as to convert the conductivity of the implanted portion to the first conductivity type to form the first semiconductor connective region which electrically connects the second semiconductor well region to the bulk portion of the semiconductor body.

Viewed from a second method aspect, the present invention is directed to a method of forming a first semiconductor connective region of a first conductivity type through a semiconductor layer of a second opposite conductivity type which at least partly separates a second semiconductor well region of the first conductivity type from a bulk portion of a semiconductor body of the first conductivity type so as to electrically connect the well region to the bulk portion of the semiconductor body. The method comprises the steps of implanting ions of the first conductivity type into a portion of the semiconductor layer, and heating the semiconductor body so as to cause the implanted ions to diffuse through portions of the semiconductor layer so as to convert a portion of the semiconductor layer extending from the semiconductor well region to the bulk portion of the semiconductor to the first conductivity type to form the first semiconductor connective region that electrically connects the second semiconductor well region to the bulk portion of the semiconductor body.

Viewed from a third method aspect, the present invention is directed to a method of forming a first semiconductor connective region of a first conductivity type through a semiconductor layer of a second opposite conductivity type which, with second semiconductor regions of the second conductivity type that are in contact with the layer, electrically isolate a third semiconductor well region of the first conductivity type from a bulk portion of a semiconductor body of the first conductivity type. The method comprises the steps of implanting ions of the first conductivity type into a portion of the semiconductor layer, and heating the semiconductor body so as to cause the implanted ions to diffuse through portions of the semiconductor layer so as to convert a portion of the semiconductor layer extending from the third semiconductor well region to the bulk portion of the semiconductor to the first conductivity type to form the first semiconductor connective region which electrically connects the third semiconductor well region to the bulk portion of the semiconductor body.

Viewed from an apparatus aspect, the present invention is directed to an apparatus comprising a semiconductor body having a top surface and having a bulk portion of a first conductivity type, a semiconductor layer of a second opposite conductivity type being located below the top surface, a semiconductor well region of the first conductivity type being at least partly separated from the bulk portion of the semiconductor body by the semiconductor layer, and a semiconductor connective region of the first conductivity type extending through a portion of the semiconductor layer so as to electrically connect the well region to the bulk of the semiconductor body. The connective region is formed by implantation of ions of the first conductivity type into a portion of the semiconductor layer.

The present invention will be better understood from the following more detailed description taken with the accompanying drawings and claims.

### BRIEF DESCRIPTION OF THE DRAWINGS

FIG. 1 shows a sectional view of an integrated circuit structure fabricated in accordance with a method of the present invention;

FIG. 2 shows a sectional view of the integrated circuit structure of FIG. 1 at one stage of fabrication; and

FIG. 3 shows a sectional view of the integrated circuit structure of FIG. 2 at a later stage of fabrication.

### DETAILED DESCRIPTION

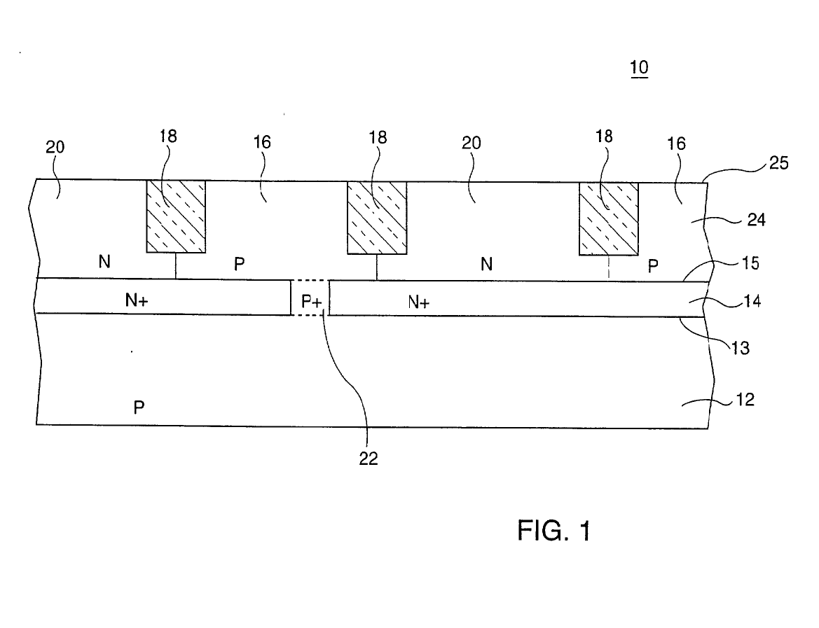

FIG. 1 shows a sectional view of an integrated circuit structure 10 fabricated in accordance with an exemplary embodiment of the present invention. The structure 10 comprises a bulk portion of a semiconductor body 12 of a first conductivity type, for example of p-type conductivity, having a top surface 13. A buried semiconductor layer 14 of a second conductivity type, for example of n-type conductivity, having an upper surface 15, p-type semiconductor wells 16 of the first conductivity type, n-type semiconductor wells 20 of the second conductivity type, and isolation regions 18, typically of silicon oxide, have been fabricated in the integrated circuit structure 10 using prior art methods. A region 22 of the first conductivity type, i.e., p-type, has been formed using the methods of the present invention to provide a conductive (electrical) connection between the p-well 16 and the p-type bulk portion of the semiconductor body 12.

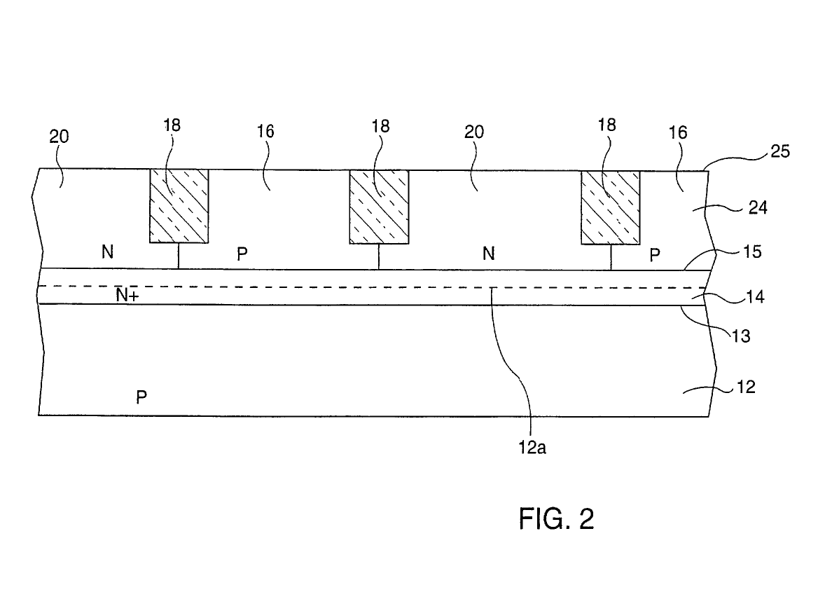

FIG. 2 shows a sectional view of the semiconductor structure 10 of FIG. 1 at one stage of fabrication. This structure comprises a bulk portion of the semiconductor body 12 of p-type conductivity, having a top surface 13, and which had, prior to the fabrication steps described below, an original top surface 12a (shown as a dashed line) above surface 13. Impurity atoms which are n-type dopants are ion implanted into the original surface 12a of the bulk portion of the semiconductor body 12. A layer of semiconductor material 24 having a surface 25 is then epitaxially grown on the original surface 12a of the bulk portion of the semiconductor body 12. The semiconductor structure is then subjected to an annealing step to repair damage to the crystallographic structure of the body 12 resulting from ion implantation and to diffuse the n-type implanted impurity downward into the bulk portion of the semiconductor body 12 and upward into the epitaxial layer 24. This forms a buried layer 14 of n-type conductivity, with a top surface 15, and also forms a top surface 13 of the bulk portion of the semiconductor body 12. Shallow Trench Isolation (STI) regions 18 are defined using photolithographic and etching techniques, and filled with an insulating material, typically silicon oxide. The p-well regions 16 and n-well regions 20 are then defined and doped to their appropriate conductivity type and concentration. After the regions 16 have been defined using photolithographic techniques, impurity atoms of p-type dopants are then ion implanted into the surface 25 of the epitaxial layer 24. After the regions 20 have been defined using photolithographic techniques, impurity atoms of n-type dopants are then ion implanted into the surface 25 of the epitaxial layer 24. The semiconductor structure 10 is then subjected to an annealing step to diffuse the ion implanted impurity atoms throughout the regions 16 and 20. The above fabrication is performed using industry standard techniques.

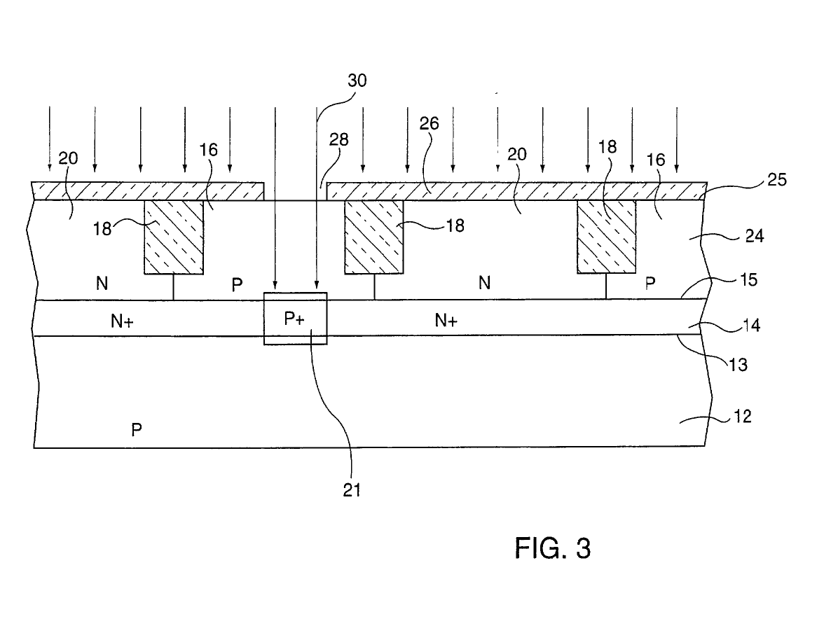

FIG. 3 shows the semiconductor structure 10 after an ion implantation mask 26 is deposited on the surface 25 of the epitaxial layer 24. An opening 28 in the ion implantation mask 26 is defined and patterned using conventional photolithographic and etching techniques. Impurity atoms 30 of p-type dopants are then implanted through the opening 28 in the ion implantation mask layer 26. An ion implantation of one energy, or if necessary a multiplicity of implantations at different ion energies, doses, or beam angles, is used to implant atoms into a region 21 which includes portions of the buried layer 14 underneath the opening 28 in the ion implantation mask 26, and extends past the upper surface 15 of the buried layer 14 into the p-well region 16 and beneath the upper surface 13 into the bulk portion of the p-type semiconductor body 12.

FIG. 1 shows the structure of FIG. 3 after the ion implantation mask 26 has been removed and the semiconductor structure 10 has then subjected to an annealing step to repair damage to the crystallographic structure of the semiconductor body 12 resulting from ion implantation and to activate the implanted p-type dopant ions to form a p-type region 22. As shown in FIG. 1, the p-type region 22 provides a conductive (electrical) connection between the p-well 16 and the p-type body 12.

When using the methods of the present invention it has been found possible to define a converted region 22 of the semiconductor layer 14 with a lateral dimension, or width, of typically 0.4 micrometer. In contrast, when using the prior art technique of masking the implant of ions into the surface 12a of bulk semiconductor region 12 to form regions where the layer 14 is not present, the minimum width of such an opening in layer 14 is typically found to be 1.0 micrometer. The minimum size of a semiconductor well 16 is found to be 0.6 micrometer. The ion implanted conductive connection fabricated using the methods of the present invention can thus be used to connect a semiconductor well 16 to a bulk semiconductor region 12 through a semiconductor layer 14 without any increase in the minimum size of semiconductor well 16 which can be used in a given design of CMOS integrated circuit.

While the details of the method of forming the conductive region 22 in FIG. 1 were described above in terms of a semiconductor structure containing p-wells 16 of a first conductivity type, n-wells 20 of a second conductivity type, and isolation regions 18, the method is equally applicable to a structure containing multiple n and p-wells of different doping characteristics and depth, and to structures wherein the isolation between different p-wells may be regions of a second conductivity type with a doping characteristic and depth chosen to optimize the isolation characteristics of the region. Further, the method of the present invention for providing a conductive connection between various wells and the bulk portion of the semiconductor body may be applied selectively to only a portion of the wells of the first conductivity type, while other of the wells of the first conductivity type remain floating, or connected to various reference potentials through other means.

It can be readily appreciated that the specific embodiment described is merely illustrative of the basic principles of the invention and that various other embodiments may be devised without departing from the spirit and novel principles of the invention. It can be readily appreciated that the specific process steps and sequence of said process steps is merely illustrative of the basic principles of the invention, and that various other steps may be devised, and the sequence of said process steps may be modified, without departing from the spirit and novel principles of the invention. For example, it may be desirable to form the novel conductive interconnection through a p-type buried layer between an n-type well and an n-type bulk portion of the semiconductor body. Still further, while the structure and method are described in the context of fabricating a silicon complementary MOS integrated circuit, the method may be applied to fabricating silicon integrated circuits using a single channel type of MOS transistor, or to fabricating integrated circuits using single or complementary bipolar transistors, or to fabricating silicon integrated circuits utilizing any combination of n or p-channel MOS transistors and npn or pnp bipolar transistors. Furthermore, the method may be applied to fabricating integrated circuits using semiconductors other than silicon.

1. A method of forming a first semiconductor connective region of a first conductivity type through a semiconductor layer of a second opposite conductivity type which at least partly separates a second semiconductor well region of the first conductivity type from a bulk portion of a semiconductor body of the first conductivity type, said method comprising the step of implanting ions of the first conductivity type into a portion of the semiconductor layer so as to convert the conductivity of the implanted portion to the first conductivity type to form the first semiconductor connective region which electrically connects the second semiconductor well region to the bulk portion of the semiconductor body.

2. The method of claim 1 wherein the semiconductor body and the second semiconductor well region share a common top surface and the semiconductor layer is located away from the top surface.

3. The method of claim 1 wherein the well region is electrically isolated from the bulk portion of the semiconductor body, except for the connective region, by the semiconductor layer and by third semiconductor regions of the second conductivity type which are in contact with the semiconductor layer.

4. The method of claim 1 wherein the well region is electrically isolated from the bulk portion of the semiconductor body, except for the connective region, by the semiconductor layer, the third semiconductor regions of the second conductivity type which are in contact with the semiconductor layer, and insulating regions.

5. A method of forming a first semiconductor connective region of a first conductivity type through a semiconductor layer of a second opposite conductivity type which at least partly separates a second semiconductor well region of the first conductivity type from a bulk portion of a semiconductor body of the first conductivity type so as to electrically connect the well region to the bulk portion of the semiconductor body, said method comprising the steps of:
implanting ions of the first conductivity type into a portion of the semiconductor layer; and
heating the semiconductor body so as to cause the implanted ions to diffuse through portions of the semiconductor layer so as to convert a portion of the semiconductor layer extending from the semiconductor well region to the bulk portion of the semiconductor to the first conductivity type to form the first semiconductor connective region that electrically connects the second semiconductor well region to the bulk portion of the semiconductor body.

6. The method of claim 5 wherein the semiconductor body and the second semiconductor well region share a common top surface and the semiconductor layer is located away from the top surface.

7. The method of claim 5 wherein the well region is electrically isolated from the bulk portion of the semiconductor body, except for the connective region, by the semiconductor layer and by third semiconductor regions of the second conductivity type which are in contact with the semiconductor layer.

8. The method of claim 5 wherein the well region is electrically isolated from the bulk portion of the semiconductor body, except for the connective region, by the semiconductor layer, the third semiconductor regions of the second conductivity type which are in contact with the semiconductor layer, and insulating regions.

9. A method of forming a first semiconductor connective region of a first conductivity type through a semiconductor layer of a second opposite conductivity type which, with second semiconductor regions of the second conductivity type that are in contact with the layer, electrically isolate a third semiconductor well region of the first conductivity type from a bulk portion of a semiconductor body of the first conductivity type, said method comprising the steps of:
implanting ions of the first conductivity type into a portion of the semiconductor layer; and
heating the semiconductor body so as to cause the implanted ions to diffuse through portions of the semiconductor layer so as to convert a portion of the semiconductor layer extending from the third semiconductor well region to the bulk portion of the semiconductor to the first conductivity type to form the first semiconductor connective region which electrically connects the third semiconductor well region to the bulk portion of the semiconductor body.

10. The method of claim 9 wherein the semiconductor body and the third semiconductor well region share a common top surface and the semiconductor layer is located in the semiconductor body away from the top surface.

11. The method of claim 9 wherein the third semiconductor well region is electrically isolated from the bulk portion of the semiconductor body, except for the connective region, by the semiconductor layer, by the second semiconductor regions, and by insulating regions.

12. Apparatus comprising:
a semiconductor body having a top surface and having a bulk portion of a first conductivity type;
a semiconductor layer of a second opposite conductivity type being located below the top surface;
a semiconductor well region of the first conductivity type being at least partly separated from the bulk portion of the semiconductor body by the semiconductor layer; and
a semiconductor connective region of the first conductivity type extending through a portion of the semiconductor layer so as to electrically connect the well region to the bulk of the semiconductor body, the connective region being formed by implantation of ions of the first conductivity type into a portion of the semiconductor layer.
